(19) United States
(12) Patent Application Publication
(10) Pub. No.: US 2017/0222034 A1
(43) Pub. Date: Aug. 3, 2017

(54) METHOD FOR FORMATION OF VERTICAL CYLINDRICAL GaN QUANTUM WELL TRANSISTOR

(71) Applicant: Zing Semiconductor Corporation, Shanghai (CN)

(72) Inventors: Deyuan Xiao, Shanghai (CN); Richard R. Chang, Shanghai (CN)

(21) Appl. No.: 15/491,988

(22) Filed: Apr. 20, 2017

Related U.S. Application Data
(62) Division of application No. 15/077,867, filed on Mar. 22, 2016.

(30) Foreign Application Priority Data
Oct. 27, 2015 (CN) 201510707771.9

(51) Int. Cl. H01L 29/778; H01L 29/66; H01L 29/12; H01L 29/20

(52) U.S. Cl. CPC H01L 29/7788; H01L 29/2003; H01L 29/66462; H01L 29/127; H01L 29/66977

(57) ABSTRACT

The present invention provides a method for forming a quantum well device having high mobility and high breakdown voltage with enhanced performance and reliability. A method for fabrication of a Vertical Cylindrical GaN Quantum Well Power Transistor for high power application is disclosed. Compared with the prior art, the method of forming a quantum well device disclosed in the present invention has the beneficial effects of high mobility and high breakdown voltage with better performance and reliability.

The present application is a divisional application of the U.S. application Ser. No. 15/077,867 filed on Mar. 22, 2016, which claims the priority to Chinese Patent Applications No. 201510707771.9, filed with the Chinese State Intellectual Property Office on Oct. 27, 2015, which is incorporated herein by reference in its entirety.

### TECHNICAL FIELD

The present invention relates to semiconductor manufacturing, and more particularly relates to a method for forming a quantum well device.

### BACKGROUND

The basic structure of a high electron mobility transistor, HEMT, has a heterojunction with source and drain formed by modulation-doped channel layer and donor-supply layer. The two dimensional electron gas, 2-DEG, generated in the thin junction layer, confined by quantum effects to a thin sheet, are free to move along this thin layer without hindrance and interference of doped ionized impurities, resulting high electron mobility allowing fast response times and low noise operation. HEMT is a voltage control device. The gate voltage Vg can be regulated to control the depth of the heterojunction potential well, thereby controlling the surface density of 2-DEG in the potential well, and as a result, controlling the device operating current. For GaAs based HEMT, normally the n-AlₓGa₁₋ₓAs control layer is heavily doped and remains depleted. For depletion mode device, the n-AlₓGa₁₋ₓAs layer is thicker and heavily doped, 2-DEG exist even at V_{g}=0. Otherwise when the device is enhancement-mode, at V_{g}=0, Schottky depletion layer extended to GaAs layer. Hence, for HEMT, the main influencing factor is the doping density and the especially the thickness of wide band gap semiconductor layer. The surface density of 2-DEG, Nₛ, in HEMT, is mainly influenced by the sub-band of potential well of the heterojunction (i=0 and 1). 2-DEG surface charge density is V_{g} regulated.

### SUMMARY

The purpose of the present invention is to provide a method for forming a quantum well devices with high mobility. The steps of forming the quantum well device comprising:

Providing a substrate, forming on the surface of the substrate a buffer layer having a fin structure; sequentially depositing materials on the surface of the fin structure buffer layer to form the quantum well channel layer, the barrier layer and the dielectric layer; forming a metal gate on the surface of the dielectric layer on both sides of the fin structure, the metal gate height is lower than the height of the fin structure; forming sidewalls on both sides of the surface of the exposed dielectric layer and on both sides of the fin structure metal gate; sequentially etching the fin-like structure to expose the source and drain regions of the quantum well channel layer and the dielectric barrier layer; doping in the exposed surface of the quantum well channel layer to form the source and drain electrodes; forming electrodes on said source and drain.

Furthermore, the steps of forming a fin structure buffer layer on the substrate comprise: forming a buffer layer on the substrate; Forming the patterned photoresist on the surface of the buffer layer; dry etching the buffer layer which is covered by the masking patterned photoresist to form a fin structure buffer layer. Further, in the method for forming a quantum well device, the buffer layer is made of AlN, having a thickness in the range of from 100 nm to 5000 nm. Further, in the method for forming a quantum well device, the buffer layer is deposited using MOCVD, ALD or MBE process. Further, in the method for forming a quantum well device, the material of the quantum well channel layer is N-type GaN, having a thickness in the range of from 1 nm to 100 nm. Further, in the method for forming a quantum well device, the barrier layer is made of AlN. Further, in the method for forming a quantum well device, the quantum well channel layer and the barrier layer are formed using an epitaxial growth process. Further, in the method for forming a quantum well device, said dielectric layer is made of silica, alumina, zirconia or hafnia, having a thickness in the range of from 1 nm to 5 nm. Further, in the method for forming a quantum well device, the dielectric layer is formed using CVD, MOCVD, ALD or MBE process. Further, in the method for forming the quantum well devices, the metal gate material is NiAu or CrAu. Further, in the method for forming a quantum well device, the metal layer is formed using CVD, PVD, MOCVD, ALD or MBE process. Further, in the method for forming the quantum well device, the sidewall spacer is made of silicon nitride. Further, in the method of forming the quantum well devices, a selective etching process is used to successively etch the fin-like structure and the exposed surface of the buffer layer and the barrier layer dielectric layer to expose the source and drain region of the quantum well channel layer. Further, in the method for forming the quantum well devices, the ion implantation or ion diffusion process is applied to the quantum well channel layer for N⁺ ion implantation to form the source and drain.

In the present invention, it is also proposed a quantum well device using the method for forming a quantum well device described above, characterized by comprising: a substrate, a buffer layer with a fin-like structure, a quantum well channel layer, a barrier layer, a metal gate, dielectric layer, spacers and the source and drain, wherein said buffer layer having a fin-like structure is formed on said substrate; said quantum well channel layer, barrier layer, dielectric layer and gate electrode are sequentially formed on both sides of the fin structure; the sidewall spacers are formed on the surface of both sides of the fin structure where the dielectric layer is exposed and on both sides of the metal gate; said source electrode is formed in both sides of the quantum well channel layer on either side of the metal gate; said drain electrode is formed at the top of the fin structure where the quantum well channel layer is exposed.

Furthermore, said quantum well device comprising source and drain and electrodes are formed on said source and drain. Compared with the prior art, the method of forming a quantum well device disclosed in the present invention has the beneficial effects of high mobility and high breakdown voltage, so as to obtain a quantum well device with better performance and reliability.

### BRIEF DESCRIPTION OF THE DRAWINGS

FIG. 1 is the process flow diagram of forming the quantum well devices according to one embodiment of the present invention;

FIGS. 2 to 9 are cross-sectional views of material structures in the process of forming the quantum well device according to one embodiment of the present invention.

### DETAILED DESCRIPTION

Below is a more detailed description with schematic drawings to illustrate the method of forming the quantum well device which is a preferred embodiment of the present invention. It should be understood that those skilled in the art may modify the invention herein described while still achieving the beneficial effects of the invention. Thus, the following description should be construed as widely known to the skilled person, and not as a limitation of the present invention.

The description of the embodiment herein is for the clarity of the method of making the device of this invention, not for describing all the detailed features of forming an actual embodiment. In the following description, not all the well-known functions and structures are described in detail, as they may present unnecessary details and causing confusion. In the development of any actual embodiment or making any change to the embodiment described herein, the implementation details must be considered in order to meet a large number of specific requirements, for example, the constraints of the system and the commercial application. In addition, it should be considered that such a development effort might be complex and time-consuming, but for the skilled artisans they are merely routine works.

In the following paragraphs, the present invention is described more specifically by utilizing specific examples in reference to the accompanying drawings. According to the following description and claims, advantages and features of the present invention will become more apparent. It should be noted however that the drawings, of simplified version and of approximate dimensions, are meant to facilitate more clearly the description of the embodiment of the present invention.

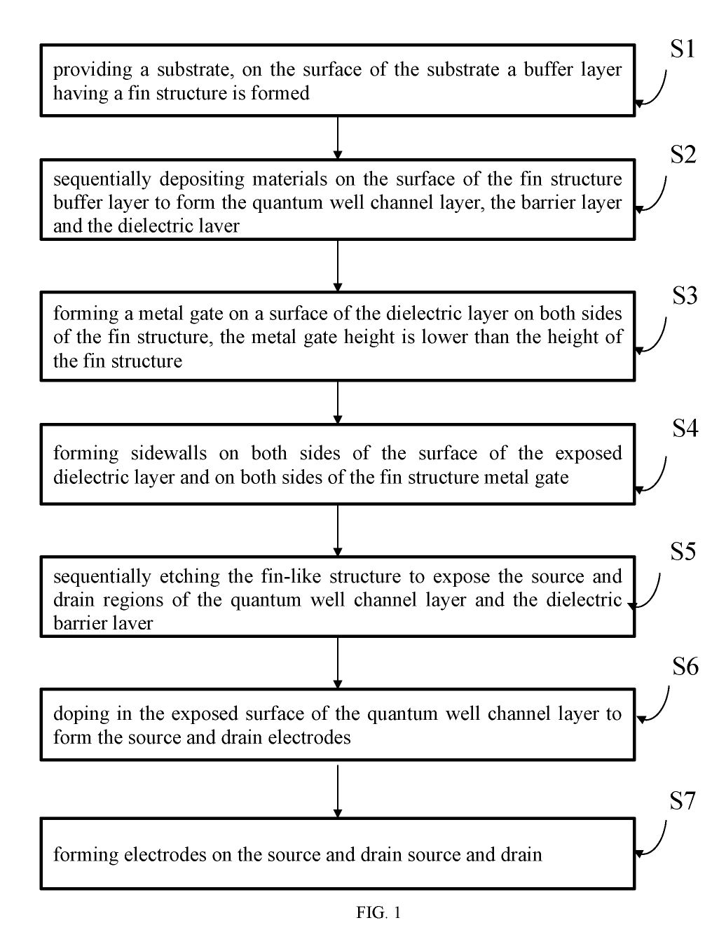

The following paragraphs, with reference to the accompanying drawings by way of example, are to describe the present invention more specifically. According to the following description and claims, advantages and features of the present invention will become more apparent. It should be noted that the drawings are prepared in a very simplified form and are not drawn to scale precisely in proportion, only for the purpose of providing as an auxiliary to facilitate the clear explanation of the embodiment of the present invention. Referring to FIG. 1, the present invention proposes a method of forming a quantum well device, comprising the steps of:

S100: providing a substrate, on the surface of the substrate a buffer layer having a fin structure is formed;

S200: sequentially depositing materials on the surface of the fin structure buffer layer to form the quantum well channel layer, the barrier layer and the dielectric layer;

S300: forming a metal gate on a surface of the dielectric layer on both sides of the fin structure, the metal gate height is lower than the height of the fin structure;

S400: forming sidewalls on both sides of the surface of the exposed dielectric layer and on both sides of the fin structure metal gate;

S500: sequentially etching the fin-like structure to expose the source and drain regions of the quantum well channel layer and the dielectric barrier layer;

S600: doping in the exposed surface of the quantum well channel layer to form the source and drain electrodes;

S700: forming electrodes on the source and drain source and drain.

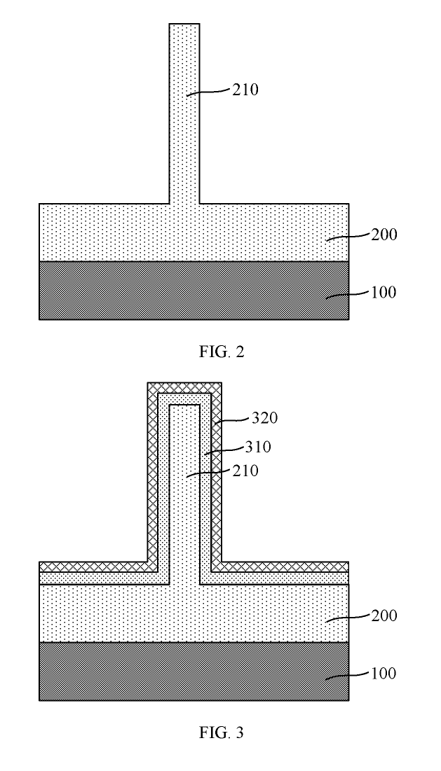

Specifically, referring to FIG. 2, in step S100, the substrate 100 may be a silicon substrate, a sapphire substrate or a SiC substrate. The substrate may also be provided with Σ-shaped groove or groove of the other graphics. In the surface of substrate 100 a buffer layer 200 is formed; the buffer layer 200 is made of AlN, having a thickness in the range of from 100 nm to 5000 nm, for example, 3000 nm. The buffer layer 200 may be formed employing MOCVD (Metal-organic Chemical Vapor Deposition, metal organic chemical vapor deposition), ALD (Atomic layer deposition, atomic layer deposition) or MBE (Molecular Beam Epitaxy, molecular beam epitaxy) process.

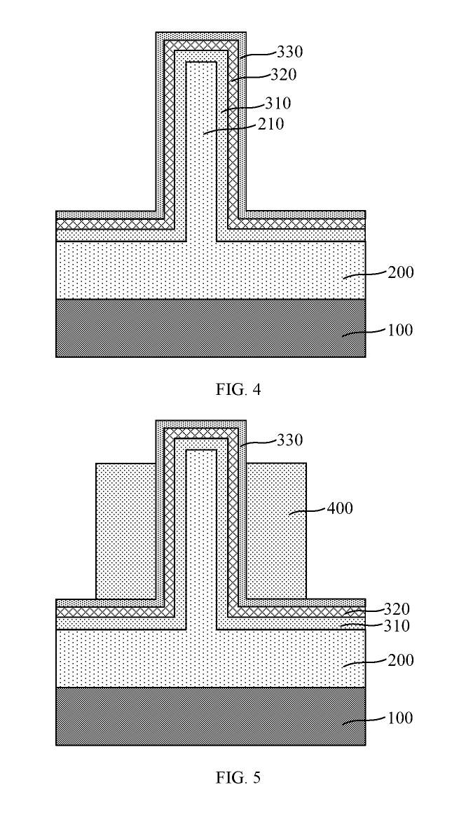

Next, the fin structure 210 is formed on the buffer layer 200, wherein the forming step comprises: Forming the buffer layer on the substrate; the patterned photoresist is formed on the surface of the buffer layer; using the patterned photoresist as a mask, dry etching the buffer layer, to form a fin structure (Fin). Next, referring to FIG. 3 and FIG. 4, on the surface of the buffer layer 200 and the fin structure 210, the quantum well channel layer 310, barrier layer 320 and dielectric layer 330 are sequentially deposited; wherein, said quantum well channel layer 310 is formed using N-type material GaN in the present embodiment, which has a thickness in the range of from 1 nm to 100 nm, for example, 50 nm. The barrier layer 320 is made of AlN. The dielectric layer 330 is made of silica, alumina, zirconia or hafnia having a thickness in the range of from 1 nm to 5 nm, for example, 3 nm. Wherein the quantum well channel layer 310, barrier layer 320 and dielectric layer 330 are formed using CVD, MOCVD, ALD or MBE.

Next, referring to FIG. 5, the metal gate electrode 400 is formed on surfaces of both sides of the fin structure dielectric layer 330. The height of metal gate 400 is lower than the height of the fin structure 210; wherein, said metal gate electrode 400 is made by using materials like NiAu or CrAu, which is deposited using PVD (Physical Vapor Deposition, physical vapor deposition), MOCVD, ALD or MBE process.

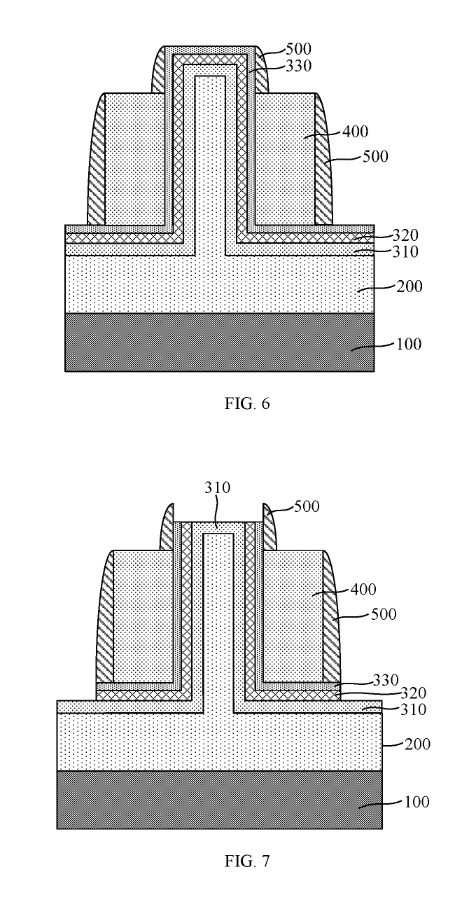

Next referring to FIG. 6, spacer 500 is formed on both surfaces of the metal gate 400 and the fin structure surfaces where the dielectric layer 330 is exposed. The sidewall spacer 500 is made of silicon nitride.

Next, referring to FIG. 7, the fin structure 210 and the buffer layer 200 are etched to remove portions of the dielectric layer 330 and barrier layer 320 so as to reveal the source and drain regions of the quantum well channel layer 310; wherein selective etching process is applied to remove the portion of the dielectric layer 330 and barrier layer 320 to expose the channel layer 310 located on top of the fin structure for drain, and the quantum well channel layers 310 on both sides of the buffer layer 200 and metal gate 400, for source.

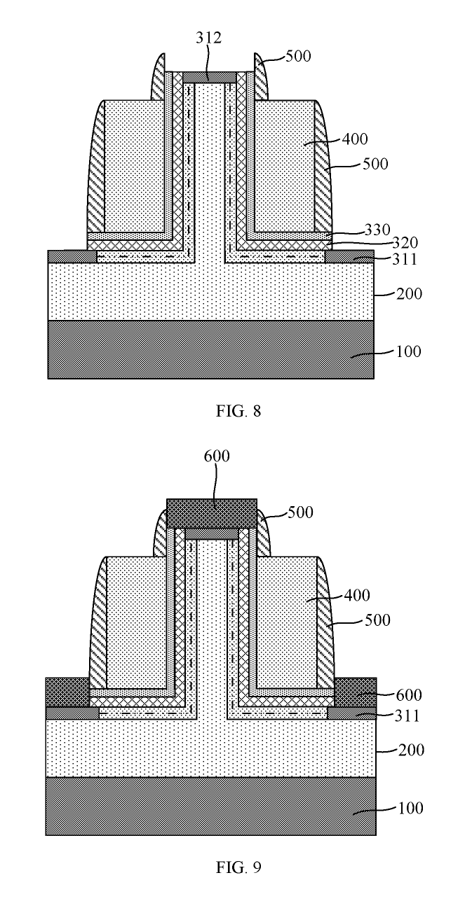

Next, referring to FIG. 8, the quantum well channel layer 310 is N⁺ ion implanted using ion implantation or ion diffusion process to form the source 311 and drain 312. The quantum well layer 310, barrier layer 320 and the source 311 and drain 312 structure form a heterojunction. The two-dimensional electron gas (2-DEG, as shown in dashed lines) generated in the modulation doped quantum well layer 310 is able to move freely without the interference of ionized impurity, achieving very high mobility and enhanced device performance.

Next, referring to FIG. 9, the source and drain electrodes 600 are formed on the source 311 and drain 312.

In another embodiment of the present invention, a quantum well device is proposed using the forming method described above, comprising: a substrate 100 with a buffer layer 200 having a fin structure 210, a quantum well the channel layer 310, barrier layer 320, a metal gate 400, dielectric layer 330, spacers 500 and source 311 and drain 312. The quantum well channel layer 310, barrier layer 320, dielectric layer 330 and the metal gate electrode 400 are sequentially formed on both sides of the fin structure 210. The sidewall spacer 500 is formed on both sides of the fin structure 210 where the dielectric layer 330 is exposed and on both sides of the metal gate 400. Said source electrode 311 is formed in the quantum well channel layer 310 on both sides of the metal gate electrode 400, the drain electrode 312 is formed on the fin structure 210 at the top of the exposed layer quantum well channel 310. Wherein the quantum well device comprises a source and drain electrode 600, the source and drain electrode 600 is formed on source 311 and drain 312.

In summary, the method disclosed in the present invention is capable of forming quantum well devices with high mobility, having higher breakdown voltage, so as to obtain better performance and reliability. The embodiment of the present invention described above is an example only and do not limit the present invention in any way. For those skilled in the art, without departing from the technical scope of the present invention, using the technical solutions and technical content disclosed herein, any form of equivalents or changes or modifications of the present invention without departing from the content of the present invention still fall within the scope of the present invention.

What is claimed is:

1. A quantum well device comprising:
a substrate, a buffer layer with a fin-like structure, a quantum well channel layer, a barrier layer, a metal gate, dielectric layer, spacers, and source and drain electrodes, wherein said a buffer layer having a fin structure is formed on said substrate, said quantum well channel layer, a barrier layer, dielectric layer and metal gate are sequentially formed on both sides of the fin structure, the sidewall spacer is formed on both sides of the fin structure on both sides of the exposed surface of the dielectric layer and the metal gate, the source metal electrode is formed on both sides of the quantum well channel layer, the drain metal electrode is formed in the top of the fin structure where the quantum well channel layer is exposed.

2. The quantum well device according to claim 1, further comprising a source electrode and a drain electrode, the source electrode and the drain electrode formed on said source and drain.

3. A system comprising:
a quantum well device including:
a substrate, a buffer layer with a fin-like structure, a quantum well channel layer, a barrier layer, a metal gate, dielectric layer, spacers, and source and drain electrodes, wherein said a buffer layer having a fin structure is formed on said substrate, said quantum well channel layer, a barrier layer, dielectric layer and metal gate are sequentially formed on both sides of the fin structure, the sidewall spacer is formed on both sides of the fin structure on both sides of the exposed surface of the dielectric layer and the metal gate, the source metal electrode is formed on both sides of the quantum well channel layer, the drain metal electrode is formed in the top of the fin structure where the quantum well channel layer is exposed.

4. The system according to claim 3, further comprising a source electrode and a drain electrode, the source electrode and the drain electrode formed on said source and drain.
